(19) United States
(12) Patent Application Publication
(10) Pub. No.: US 2025/0151185 A1
(43) Pub. Date: May 8, 2025

(54) NEUTRAL-LESS DIMMERS WITH A ZERO CROSSING DETECTION IMPROVEMENT CIRCUIT

(71) Applicant: EATON INTELLIGENT POWER LIMITED, DUBLIN 4 (IE)

(72) Inventors: Martin Hampl, Mohelnice (CZ); Justin Franke, Sharpsburg, GA (US); Hoon Lee, Sugar Hill, GA (US); Nilesh Kadam, Pune (IN)

(73) Assignee: EATON INTELLIGENT POWER LIMITED, DUBLIN 4 (IE)

(21) Appl. No.: 18/931,363

(22) Filed: Oct. 30, 2024

Related U.S. Application Data
(60) Provisional application No. 63/547,778, filed on Nov. 8, 2023.

(51) Int. Cl. H05B 47/10; H03K 17/13; H05B 45/31; H05B 45/3575; H05B 45/39

(52) U.S. Cl. CPC H05B 47/10; H05B 45/31; H05B 45/3575; H05B 45/39; H03K 17/133

(57) ABSTRACT

A dimmer includes a TRIAC, a zero crossing detection circuit coupled to the TRIAC and structured to detect zero crossing of line voltage; a gate control circuit coupled to a gate of the TRIAC and the zero crossing detection circuit, the gate control circuit structured to drive the gate of the TRIAC to switch between an on phase and an off phase; a power supply circuit coupled to the gate control circuit and the zero crossing detection circuit, the power supply circuit structured to supply power to at least the gate control circuit and the zero crossing detection circuit; a snubber circuit coupled to the TRIAC and structured to limit fast transient voltages; and a zero crossing detection improvement circuit comprising a first switch and a second switch and structured to block current from flowing through the power supply circuit and the snubber circuit during the off phase.

### CROSS REFERENCE TO RELATED APPLICATIONS

This application claims priority to U.S. Patent Application Ser. No. 63/547,778, filed Nov. 8, 2023, entitled NEUTRAL-LESS DIMMERS WITH A ZERO CROSSING DETECTION IMPROVEMENT CIRCUIT, which is incorporated herein by reference in its entirety.

### FIELD OF THE INVENTION

The disclosed concept relates generally to dimmers, and in particular neutral-less two-wire dimmers with a zero crossing detection improvement circuit.

### BACKGROUND OF THE INVENTION

Dimmers provide a dimming function for loads such as lights. Dimmers are generally placed between a power source and the loads and control the nature of the power provided to the loads. Very simple dimmers regulate the voltage provided to the loads by, for example, dividing the voltage using a variable resistor. More recent dimmers cut off a part of each half-cycle of the power provided to the loads. In some dimmers, the cut off is from a zero crossing in the power until a predetermined time after the zero crossing. Cutting off a part of the waveform can be accomplished using a bidirectional switch such as a TRIAC (triode for alternating current). As shown in FIG. 1, conventional two-wire neutral-less dimmers 10 generally include a bidirectional power switching device (e.g., a TRIAC) 14, a snubber circuit 15, a rectifier bridge 100, a power supply circuit 200, an actuator (e.g., without limitation, a slider) 300, a gate control circuit 400, and a zero crossing detection circuit 500. The two-wire neutral-less dimmers 10 are coupled to loads 4, and form a current loop from a line conductor 3 to a neutral line 5 via the loads 4. The snubber circuit is structured to limit fast voltage transients dV/dt, particularly during switching off of an inductive load. Such a TRIAC-based dimmer has two phases: an ON phase during which the TRIAC 14 is conducting the load current and an OFF phase during which the TRIAC 14 is not conducting the load current.

The zero crossing detection is realized by measuring the voltage V_{TRIAC} across the TRIAC during the off phase. When the TRIAC 14 is turned off, the zero crossing detection circuit 500 provides a signal detecting zero crossing of the mains voltage (the line voltage Vₗᵢₙₑ). In general, the threshold for zero crossing detection is set to a higher value between, for example and without limitation, 0V to 20V, which can be easily compensated in the gate control circuit 400. During the off phase, the dimmers 10 generally include two current paths from the line 3 to the neutral 5 as shown in FIG. 2: a first path 6 via which current (I_{supply}) flows through the power supply circuit 200 and other electrical dimmer components (hereinafter, also collectively referred to as “Supply and Control electronics”) and the loads 4, and a second path 7 via which current (I_{snubber}) flows through the snubber circuit 15 and the loads 4. The amount of current flowing through the power supply circuit 200 depends on current consumption of the other electronics within the dimmer 10 such as the rectifier bridge 100, the slider 300 and the gate control circuit 400. The current consumption mainly depends on the component selection and is typically, e.g., without limitation, about 5 mA. However, the power supply current I_{supply} during the off phase has to be higher than the current consumption based on the conduction angle setting. The maximum conduction angle required by NEMA SSL7A is 130°. As such, the power supply current I_{supply} needs to be approximately three to six time higher than the current consumption. Thus, the power supply current I_{supply} during the off phase is, e.g., without limitation, approximately 15 mA. This power supply current I_{supply} flows through the loads 4, and thus the load current I_{load} becomes non-zero (e.g., without limitation, in range of 5 mA to 15 mA), thereby creating a voltage drop over the loads 4. For high power loads, which present low impedance, such voltage drop is relatively low and contributes relatively low error in zero crossing detection as compared to that in low power loads, which present high impedance.

For low power loads such as LED bulbs, however, such voltage drop is significant. For example, for a 5 W LED bulb, the impedance is equivalent to 2,880Ω and the voltage drop is about 43.2V. Further, the current I_{snubber} flowing through the snubber circuit 15 and the loads 4 results in further voltage drop over the loads 4. Due to this voltage drop created as a result of the I_{supply} and I_{snubber}, the voltage V_{TRIAC} over the TRIAC 14 is not equal to the line voltage Vₗᵢₙₑ. That is, the V_{TRIAC} is Vₗᵢₙₑ−V_{load}≠Vₗᵢₙₑ. This voltage drop over the loads 4 in turn shifts the reference point for zero-crossing detected by the zero crossing detection circuit 500, causing inaccuracy in the zero crossing detection, which now depends on the load voltage and ampere characteristics. This inaccuracy in turn results in reduction of conduction angle range of the dimmers 10. That is, the gate control circuit 400 starts to turn on the TRIAC 14 after the actual zero crossing of the line voltage due to the reference point shift, and thus limits the conduction angle. Consequently, the reduced conduction angle range reduces the observable dimming range of the dimmers 10.

There is room for improvement in zero-cross detection for dimmers, particularly dimmers for lower power loads.

### SUMMARY OF THE INVENTION:

These needs, and others, are met by embodiments of the disclosed concept in which a dimmer for lighting is provided. The dimmer is structured to be placed between a power source and a load. It includes: a TRIAC having a gate, first terminal coupled to the load and a second terminal coupled to the power source, the TRIAC being structured to conduct load current during an on phase and not conduct the load current during an off phase; a zero crossing detection circuit coupled to the first terminal of the TRIAC and structured to detect zero crossing of line voltage during the off phase; a gate control circuit coupled to the gate of the TRIAC and the zero crossing detection circuit, the gate control circuit being structured to control operation of the dimmer and drive the gate of the TRIAC to switch between the on phase and the off phase; a power supply circuit coupled to the gate control circuit and the zero crossing detection circuit, the power supply circuit structured to supply power to at least the gate control circuit and the zero crossing detection circuit; a snubber circuit coupled to the second terminal of the TRIAC and structured to limit fast voltage transients; and a zero crossing detection improvement circuit comprising a first switch coupled to an input of the power supply circuit and a second switch coupled to the snubber circuit, the first terminal of the TRIAC, the zero crossing detection circuit and the load,.

Another exemplary embodiment provides a method for improving zero crossing detection for a dimmer. The dimmer has a TRIAC, a zero crossing detection circuit, a zero crossing detection improvement circuit, a power supply circuit and a snubber circuit. The method includes switching a TRIAC (triode for alternating current) during an off phase; blocking current, by a zero crossing detection improvement circuit, from flowing through the power supply circuit and the snubber circuit during the off phase; and measuring voltage across the TRIAC during the off phase.

### BRIEF DESCRIPTION OF THE DRAWINGS:

A full understanding of the invention can be gained from the following description of the preferred embodiments when read in conjunction with the accompanying drawings in which:

FIG. 1 is a block diagram of a conventional two-wire dimmer;

FIG. 2 is an equivalent block diagram of the conventional two-wire dimmer of FIG. 1 during an off phase of a TRIAC. This block diagram illustrates two current paths when the power switching device is turned OFF;

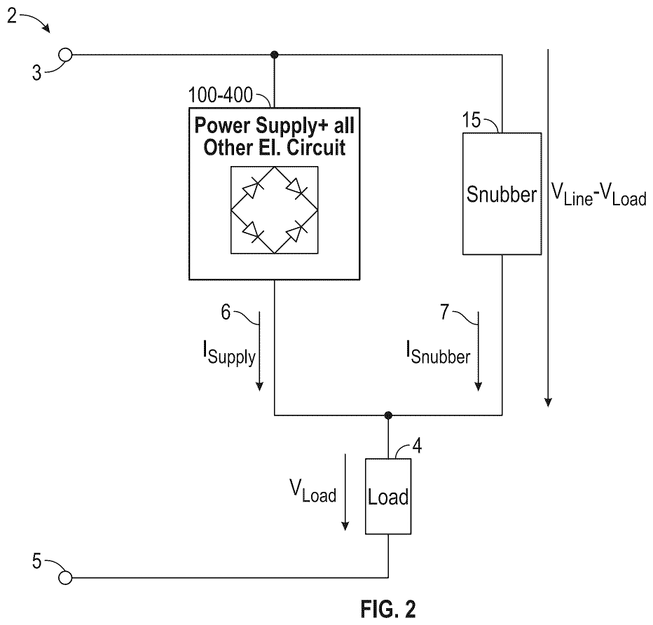

FIG. 3 is a block diagram of an exemplary dimmer with a zero crossing detection improvement circuit according to a non-limiting, example embodiment of the disclosed concept;

FIG. 4 is a TRIAC voltage wave form and a timing diagram of the operation of the zero crossing detection improvement circuit of FIG. 3 according to a non-limiting, example embodiment of the disclosed concept;

FIG. 5 is a TRIAC voltage wave form of the conventional two-wire dimmer;

FIG. 6 is a TRIAC voltage wave form using the zero crossing detection improvement circuit of FIG. 3 according to a non-limiting example embodiment of the disclosed concept; and

FIG. 7 is an equivalent block diagram of the exemplary dimmer of FIG. 3 during an off phase of a TRIAC according to a non-limiting, example embodiment of the disclosed concept.

### DETAILED DESCRIPTION OF THE INVENTION:

Directional phrases used herein, such as, for example, left, right, front, back, top, bottom and derivatives thereof, relate to the orientation of the elements shown in the drawings and are not limiting upon the claims unless expressly recited therein.

As employed herein, the statement that two or more parts are “coupled” together shall mean that the parts are joined together either directly or joined through one or more intermediate parts.

Example embodiments of the disclosed concepts provide a neutral-less dimmer with a zero crossing detection improvement circuit that controls the current flowing through the load, particularly during the time immediately around zero crossing of the AC main voltage (line voltage), while a power switching element, e.g., without limitation, a TRIAC, is in the off phase (open-circuit state). Specifically, the zero crossing detection improvement circuit reduces or blocks entirely the current flowing through paths other than the TRIAC, e.g., without limitation, the Supply and Control electronics and a snubber circuit, for a limited period (e.g., without limitation, 10-40° of the half-phase) after the actual zero crossing. For example, the zero crossing detection improvement circuit includes a first switch electrically coupled to the input of the power supply circuit and structured to block the current from flowing through the Supply and Control electronics and the loads during the off phase, and the second switch electrically coupled to the snubber circuit and structured to block the current from flowing through the snubber circuit and the loads during the off phase. Thus, by blocking the current from flowing through the loads via dimmer components other than the TRIAC during the off phase, the zero crossing detection improvement circuit reduces or eliminates the voltage drop across the loads and the zero crossing reference shift that would have resulted from the current flowing through the dimmer components other than the TRIAC and the loads as in the conventional two-wire dimmers. As such, the zero crossing detection improvement circuit significantly increases the accuracy of the zero crossing detection and renders the zero crossing detection independent of the voltage-ampere characteristic of the loads. Further, by reducing or blocking the current flowing through the dimmer components other than the TRIAC during the off phase, the zero crossing detection improvement circuit assists with reducing risk of unwanted lighting artifacts such as ghosting.

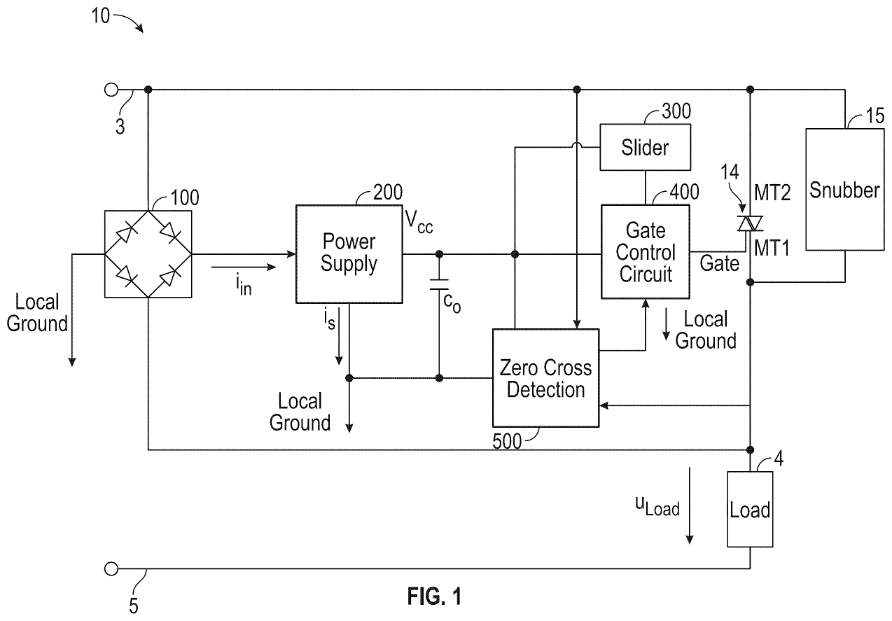

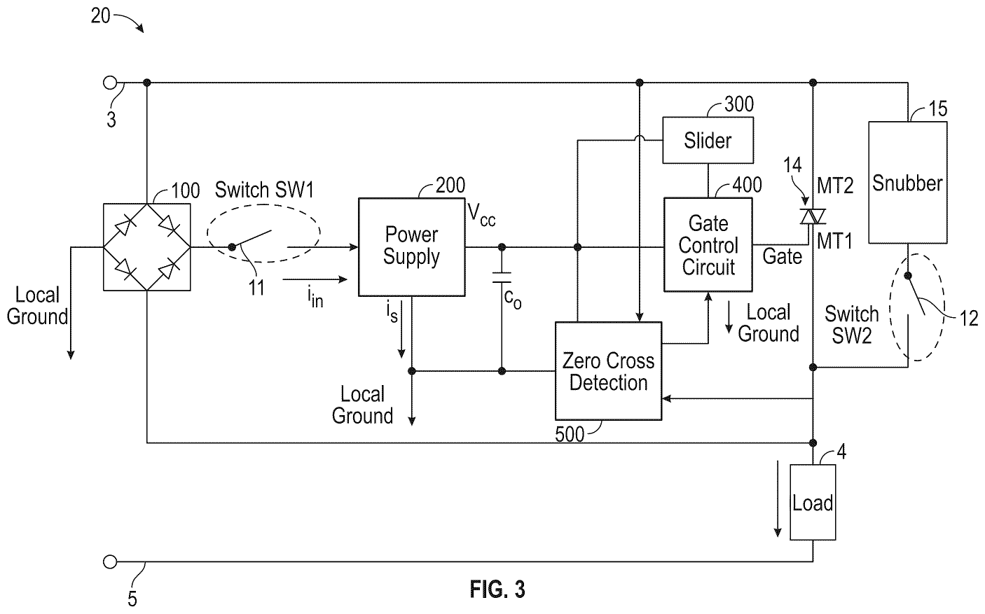

FIG. 3 is a block diagram of a dimmer 20 with a zero crossing detection improvement circuit according to a non-limiting, example embodiment of the disclosed concept. The dimmer 20 is similar to the two-wire (neutral-less) dimmers 10 of FIG. 1, except in that the dimmer 20 includes the zero crossing detection improvement circuit. As such, any overlapping descriptions of the similar components and features thereof is omitted for the sake of brevity. The dimmer 20 includes a TRIAC 14, a zero crossing detection circuit 500, a gate control circuit 400, a power supply circuit 200, a snubber circuit 15. The TRIAC 14 has a gate, first terminal (MT1) coupled to the load 4 and second terminal (MT2) coupled to the power source via line terminal 3. The zero crossing detection circuit 500 is coupled to the first terminal of the TRIAC 14 and structured to detect zero crossing of line voltage during the off phase. The gate control circuit 400 is coupled to the gate of the TRIAC 14 and the zero crossing detection circuit 500. The gate control circuit 400 is structured to control operation of the dimmer 20 and drive the gate of the TRIAC 14 to switch between the on phase and the off phase. The power supply circuit 200 is coupled to the gate control circuit 400 and the zero crossing detection circuit 500. The power supply circuit 200 is structured to supply power to at least the gate control circuit 400 and the zero crossing detection circuit 500. The snubber circuit 15 is coupled to the second terminal of the TRIAC 14 and the power source. The snubber circuit 15 is structured to limit fast voltage transients.

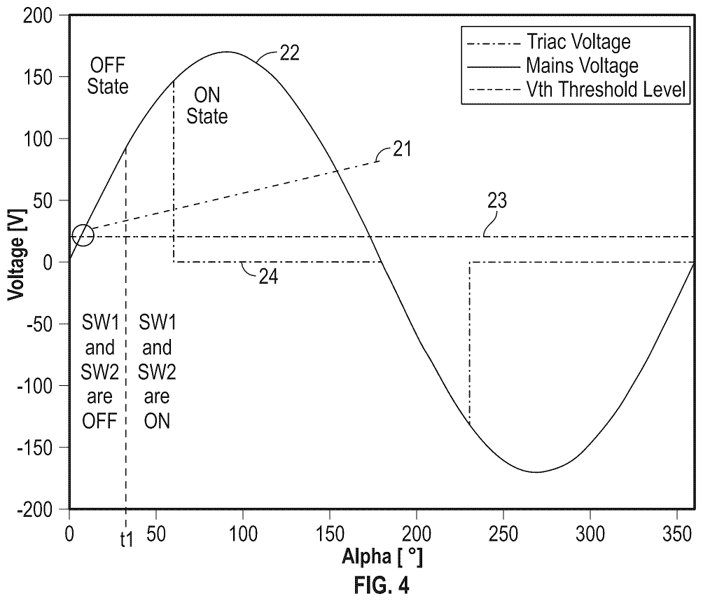

The zero crossing detection improvement circuit may include a first switch 11 electrically connected to the input of the power supply circuit 200 and a second switch 12 electrically connected to the snubber circuit 15, the first terminal of the TRIAC 14, the zero crossing detection circuit 500 and the load 4. The first switch 11 is structured to be open to block current (I_{SUPPLY}) from flowing through the power supply circuit 200 and the load 4 during a portion of the off phase of the TRIAC 14, and the second switch 12 is structured be open to block current (I_{SNUBBER}) from flowing through the snubber circuit 15 and the load 4 during the off phase of the TRIAC 14. The first and second switches 11,12 may be any type of controlled switches. For example and without limitation, the first switch 11 may be a Zener diode that blocks the I_{SUPPLY} until the line voltage is above the Zener voltage of a given Zener diode and the second switch 12 may be a bidirectional switch (e.g., without limitation, two MOSFETs). The first switch 11 is structured to block current from flowing through the power supply circuit 200 and the loads 4 for a period in which the zero crossing detection is expected to occur during a portion of the off phase of the TRIAC 14. The second switch 12 is structured to block current flowing through the snubber circuit 15 and the loads 4 for the period in which zero crossing detection is expected to occur during the off phase of the TRIAC 14. Both switches 11,12 are structured to be closed upon a lapse of the period during which the zero crossing detection is expected to occur. The operation of the first and second switches 11, 12 are discussed further in detail with reference to FIG. 4.

FIG. 4 illustrates an example timing diagram of the operation of the first and second switches 11, 12 of the zero crossing detection improvement circuit of the dimmer 20 as well as TRIAC voltage waveform 24 according to a non-limiting, example embodiment of the disclosed concept. The period in which the zero crossing detection is expected to occur commences at time zero and ends at time t1. At time zero, the conduction angle is zero and the mains voltage (line voltage) 22 is zero. At the same time, the TRIAC 14 is OFF and the first and second switches 11,12 are open. At time t1, the conduction angle may be, e.g., without limitation, between 10 to 40° and the switches 11, 12 are turned ON so that the snubber circuit 15 and the power supply circuit 200 may perform their operations. This timing, however, is for illustrative purposes only and may change depending on the design of the dimmer 20. It is to be understood that the period from time zero to t1 should last long enough to reliably detect zero crossing but short enough so as not to affect power supply performance of the power supply circuit 200. When the line voltage crosses a threshold voltage at a reference point 21, the zero crossing detection circuit 500 performs the zero crossing detection. The threshold voltage may be, e.g., without limitation, 10-20V. The threshold voltage is used for detecting zero crossing since a transistor detector or a comparator, for example, needs voltage above local ground for reliable operation. This voltage shift from 0V to the threshold voltage is not an issue because it can be easily compensated via the gate control circuit 400. The zero crossing detection is made for one polarity, i.e., in rising edges of the mains voltage.

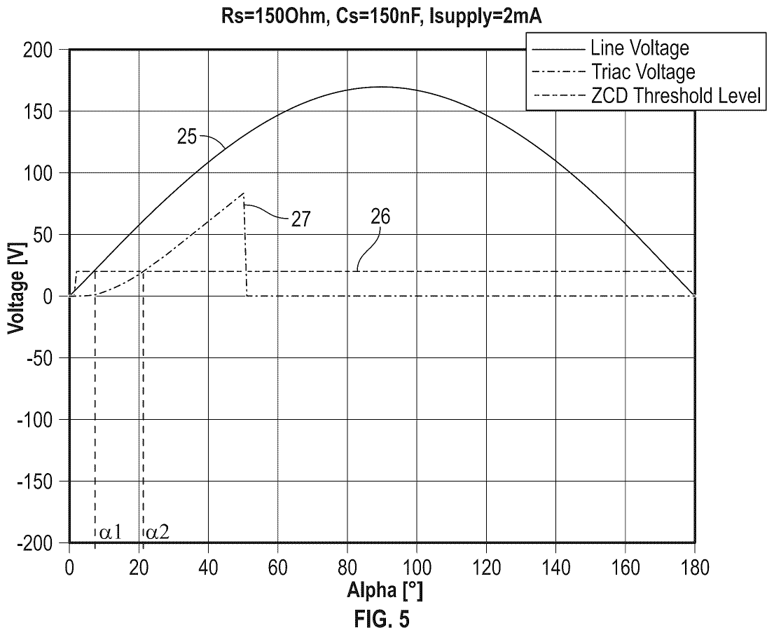

FIG. 5 illustrates a TRIAC voltage waveform 27 and line (mains) voltage waveform 25 of a zero crossing detection circuit of a conventional two-wire dimmer 10. The power supply current is constant at 2 mA, i.e., I_{supply}=2 mA and the snubber circuit 15 consists of series connection of resistor (Rs) with 150Ω and capacitor (Cs) with 150 nF. The load 4 is considered as resistive impedance with value of 5 kΩ. Conduction angle α1 is time when the input voltage is crossing the threshold level 26 for zero crossing detection. Conduction angle α2 is delayed against the conduction angle α1. The delay is caused by additional drop of the voltage across the load 4 caused by the power supply current I_{supply} and the current I_{snubber} flowing through the snubber circuit 15.

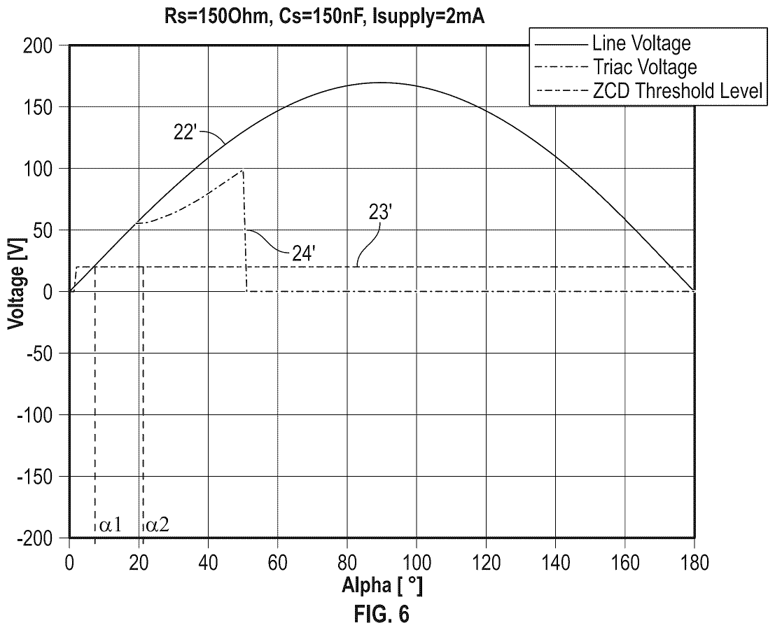

FIG. 6 illustrates an example TRIAC voltage waveform 24′ and line voltage waveform 22′ when the zero crossing detection improvement circuit of the dimmer 20 according to a non-limiting, example embodiment. The power supply current is constant at 2 mA, i.e., I_{supply}=2 mA and the snubber circuit 15 consists of series connection of resistor (Rs) with 150Ω and capacitor (Cs) with 150 nF. The load 4 is considered as resistive impedance with value of 5 kΩ. Conduction angle α1 is time when the input voltage is crossing the threshold level 23′ for zero crossing detection. Conduction angle α3 corresponds to the time when the first and second switches 11, 12 are turned ON. During the time ranging between 0 and α3, the TRIAC voltage 24′ follows exactly the line voltage 22′.

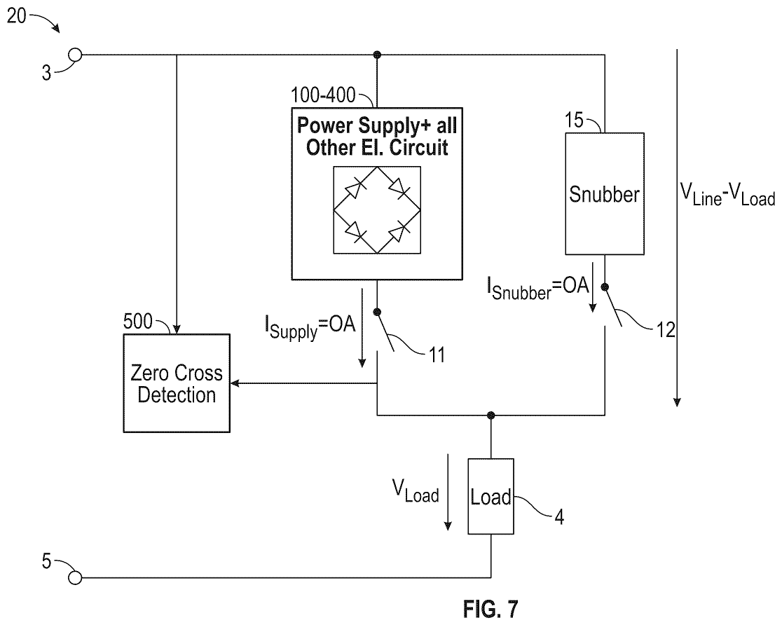

FIG. 7 is an equivalent block diagram of the exemplary dimmer of FIG. 3 during the off phase of the TRIAC 14 according to a non-limiting, example embodiment of the disclosed concept. FIG. 7 shows that the first and second switches 11,12 are both turned OFF during the period in which the zero-crossing is expected to occur. Since both the I_{supply} and I_{snubber} are equal to 0 A, there is no current flowing through the load 4, and thus the load voltage V_{load} is 0V. If V_{load}=0V, the zero crossing detection circuit 500 measures that the voltage across the TRIAC 14 is equal to the line voltage (i.e., Vₗᵢₙₑ−V_{load}=Vₗᵢₙₑ). As such, there is no error in zero crossing detection due to undesirable residual current such as the I_{supply} and I_{snubber} that flow to the loads during the off phase in the conventional dimmers 10.

Therefore, by adding the first and second switches 11,12 in the two-wire dimmer 20 in accordance with the disclosed concept, the zero crossing is independent of the load volt-ampere characteristics. Since there is no time shift in the zero crossing detection, the first and second switches 11,12 allow for the same conduction angle for all loads. Thus, the end user can use the full range of the conduction angle.

While specific embodiments of the invention have been described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of disclosed concept which is to be given the full breadth of the claims appended and any and all equivalents thereof.

What is claimed is:

1. A dimmer structured to be placed between a power source and a load, comprising:
a TRIAC (triode for alternating current) having a gate, first terminal coupled to the load and a second terminal coupled to the power source, the TRIAC being structured to conduct load current during an on phase and not conduct the load current during an off phase;
a zero crossing detection circuit coupled to the first terminal of the TRIAC and structured to detect zero crossing of line voltage during the off phase;
a gate control circuit coupled to the gate of the TRIAC and the zero crossing detection circuit, the gate control circuit being structured to control operation of the dimmer and drive the gate of the TRIAC to switch between the on phase and the off phase;
a power supply circuit coupled to the gate control circuit and the zero crossing detection circuit, the power supply circuit structured to supply power to at least the gate control circuit and the zero crossing detection circuit;
a snubber circuit coupled to the second terminal of the TRIAC and the power source, the snubber circuit being structured to limit fast voltage transients; and
a zero crossing detection improvement circuit comprising a first switch coupled to an input of the power supply circuit and a second switch coupled to the snubber circuit, the first terminal of the TRIAC, the zero crossing detection circuit and the load.

2. The dimmer of claim 1, wherein the first switch is structured to be open to block current (I_{SUPPLY}) from flowing through the power supply circuit and the load during a portion of the off phase, and the second switch is structured to be open to block current (I_{SNUBBER}) from flowing through the snubber circuit and the load during the off phase of the TRIAC.

3. The dimmer of claim 2, wherein the first switch and the second switch are structured to open at or a short time before actual zero crossing of the line voltage.

4. The dimmer of claim 3, wherein the I_{SUPPLY} and I_{SNUBBER} are zero and load voltage is zero.

5. The dimmer of claim 4, wherein the zero crossing detection circuit measures voltage across the TRIAC as equal to the line voltage.

6. The dimmer of claim 5, wherein no voltage drop over the load has resulted during the off phase based upon blocking of the current from flowing through the load via the power supply circuit and the snubber circuit by the first switch and the second switch, respectively.

7. The dimmer of claim 2, wherein the first switch and the second switch are structured to be closed upon a lapse of a period during which zero crossing detection is expected to occur.

8. The dimmer of claim 3, wherein the first switch comprises a zener diode structured to block the I_{SUPPLY} until the line voltage is above voltage of the zener diode.

9. The dimmer of claim 3, wherein the second switch comprises a bi-directional switch.

10. The dimmer of claim 9, wherein the bi-directional switch comprises two MOSFETs (metal-oxide-semiconductor field-effect transistors).

11. The dimmer of claim 1, where the zero crossing detection is realized by measuring voltage across the TRIAC during the off phase.

12. The dimmer of claim 1, wherein the zero crossing is independent of load voltage-current characteristics.

13. The dimmer of claim 1, wherein no time shift occurs in the zero crossing detection and conduction angle remains the same for all loads.

14. The dimmer of claim 13, wherein a full range of the conduction angle is used.

15. A method for improving zero crossing detection for a dimmer having a TRIAC (triode for alternating current), a zero crossing detection circuit, a zero crossing detection improvement circuit, a power supply circuit and a snubber circuit, comprising:
switching the TRIAC OFF during an off phase;
blocking current, by a zero crossing detection improvement circuit, from flowing through the power supply circuit and the snubber circuit during the off phase; and
measuring voltage across the TRIAC during the off phase.

16. The method of claim 15, wherein the zero crossing detection improvement circuit comprises a first switch coupled to an input of the power supply circuit and a second switch coupled to the snubber circuit, the first terminal of the TRIAC, the zero crossing detection circuit and the load.

17. The method of claim 16, wherein the blocking current comprises:
opening the first switch to block current (I_{SUPPLY}) from flowing through the power supply circuit and the load during a portion of the off phase of the TRIAC; and
opening the second switch to block current (I_{SNUBBER}) from flowing through the snubber circuit and the load during the off phase of the TRIAC.

18. The method of claim 17, wherein the first switch and the second switch are structured to open at or a short time before actual zero crossing of the line voltage.

19. The method of claim 17, wherein the I_{SUPPLY} and I_{SNUBBER} are zero and load voltage is zero.

20. The method of claim 19, wherein the zero crossing detection circuit measures voltage across the TRIAC as equal to the line voltage.
